(19) United States
(12) Patent Application Publication
(10) Pub. No.: US 2008/0045032 A1
(43) Pub. Date: Feb. 21, 2008

(54) Method for producing semiconductor device

(75) Inventor: Takenobu Ikeda, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 11/878,136

(22) Filed: Jul. 20, 2007

(30) Foreign Application Priority Data
Aug. 21, 2006 (JP) 2006-224174

(51) Int. Cl. H01L 21/461

(52) U.S. Cl. 438/734; 257/E21.483

(57) ABSTRACT

There is provided a method for producing a semiconductor device which forms a deep hole contact ultra-finely without generating distortion of an opening and Twisting in a contact hole. The method for producing a semiconductor device has the steps of: (a) forming a contact hole 6 in an upper part of an insulation layer 3 containing silicon oxide by dry etching using a first etching gas which contains Xe gas, and (b) deepening the contact hole 7 in the insulation layer 3 by dry etching using a second etching gas which does not contain Xe gas. It is preferable that the first etching gas contains a gas obtained by diluting an etching gas with Xe gas or with a mixed gas of Xe gas and Ar gas. It is preferable that the second etching gas contains a gas obtained by diluting an etching gas with Ar gas. It is preferable that the etching gas contains a mixed gas of a fluorocarbon gas and O₂ gas.

### BACKGROUND OF THE INVENTION

1. Field of the Invention

The present invention relates to a method for producing a semiconductor device, particularly to a method for producing a semiconductor device in which an opening is formed in an insulation layer.

2. Description of the Related Art

A dry etching process is known as a process of forming a contact hole for contacting which connects a wiring layer in a lower layer with a wiring layer in an upper layer in a semiconductor device such as DRAM. In the case of a dry etching process which provides a contact hole in a silicon oxide membrane, Ar is used as a dilution gas for improvement of vertical processability and uniformity in a semiconductor wafer plane.

In recent DRAMs, the diameter of the contact becomes ultra fine, and the contacts are placed under mutually extremely adjacent closely-spaced condition. Further, for maintaining the property of the device, increase of aspect ratio by deepening a hole is progressing. FIG. 1 shows a cross-sectional view of a semiconductor device having contact holes with high aspect ratio which were formed by a conventional technology. There are shown an interlayer insulation membrane 101, a contact 102, an interlayer insulation membrane 103, a mask 104 and a contact hole 108. In formation of the contact hole 108 with high aspect ratio in the above-mentioned circumstance, etching time in a dry etching process becomes necessarily longer, and there is a restriction that the thickness of the mask 104 can not be increased sufficiently. Therefore, as shown in the figure, a remaining membrane of the mask 104 after etching the interlayer insulation membrane 103 (silicon oxide membrane) can not be ensured sufficiently, to cause a phenomenon thereby that the opening of the contact hole 108 is distorted. Further, a phenomenon that the cross-section of the mask 104 can not be maintained in rectangular shape during etching to form a bump and to distort the mask 104 itself, promoting distortion of the opening.

Decrease and distortion of the remaining membrane of the mask lead directly mutual short circuit of the contact holes, causing decrease in yield. Thus, instead of a conventional mask formed of a photoresist using an organic membrane, introduced is a hard mask made of polysilicon, which can realize higher selection ratio against mask, or a hard mask made of amorphous carbon, which can make a releasing process simpler than polysilicon.

e used, and introduced are hard masks made of polysilicon of higher selection ratio against mask, further, of amorphous carbon of which releasing process can be made simpler than polysilicon. Simultaneously, Xe gas is being introduced which can remarkably suppress distortion of the mask occurring during dry etching, though it is very expensive. That is, it is possible to perform etching without distortion of the mask by using Xe gas or an Ar/Xe mixed gas as a dilution gas.

However, in ultra fine and high aspect structure after 90 nm generation, however, it is becoming difficult to make pattern stably with high yield only by single use thereof. The reason of this is that a phenomenon called Twisting, which never occurred before, becomes exposed. FIG. 2 shows a cross-sectional view of a semiconductor device having contact holes with higher aspect ratio which were formed by another conventional technology. There are shown an interlayer insulation membrane 101, a contact 102, an interlayer insulation membrane 103, a mask 104 and a contact hole 109. As shown in the figure, a phenomenon called Twisting in which the contact hole 109 itself can not be patterned vertically to be distorted is occurring. When this Twisting occurs, conduction between the contact 102 in a lower layer and a wiring layer in an upper layer becomes poor. This Twisting tends to occur in deeper portion of the contact hole 109, and occurs easier when using Xe gas than Ar gas.

Namely, when only Ar gas is used as the dilution gas, mutual short circuit of contact holes due to distortion of the opening is formed. When only a dilution gas containing Xe is used to suppress this short circuit, Twisting occurs. Thus, patterning of recent fine closely-spaced contact holes with high aspect ratio is becoming difficult. There is a desire, for a technology for forming an ultra fine deep hole contact which: does not cause distortion of an opening and Twisting.

As a relevant technology, Japanese Patent Application Laid-Open No. 10-98021 discloses a method for producing a semiconductor device. This method for producing a semiconductor device is characterized by etching a silicon compound layer using an etching gas containing a fluorocarbon compound, which is represented by the general formula CₘFₙ (wherein m and n represent a natural number showing atom number, satisfying a condition of m≧2, n≦2m), oxygen and an inert gas. More specifically, this method is characterized in that, during etching, the amount of a noble gas such as Ar is made smaller than in the previous step. The object is to reduce damage on ground. However, in the method of making the amount of a noble gas such as Ar smaller than in the previous step, distortion of the mask can not be suppressed. Thus, distortion of the opening can not be suppressed. Additionally, Twisting in deep hole portion can not be avoided.

As a relevant technology, Japanese Patent Application Laid-Open No. 2002-305171 discloses a method of surface treatment of a silicon-based substrate. This method of surface treatment of a silicon-based substrate is a method in which an etching treatment of target surface of the silicon-based substrate is performed by a plasma treatment. This method is characterized by containing a first plasma etching step of forming fine irregularity on the above-mentioned treatment target surface and, after the first plasma etching step, a second plasma etching step of further etching the treatment target surface by a plasma treatment using a gas for plasma generation containing a fluorine-based gas, to form a uniform white turbid etching surface. More specifically, this method is characterized by the first step using only a noble gas such as Ar and the second step using only a gas containing fluorine such as CF₄, SF₆. In etching using only a noble gas, selection ratio against mask can not be maintained at high condition and etch rate of the mask increases. Etching using only CF₄ or SF₆ can not make vertical pattern, not to be suitable for patterning at high aspect.

As a relevant technology, Japanese Patent Application Laid-Open No. 2002-110647 discloses a method for producing a semiconductor integrated circuit device. In this method for producing a semiconductor integrated circuit device, a plasma etching treatment using an etching gas containing a fluorocarbon-based gas and oxygen is performed to a silicon oxide-based insulation membrane deposited on a semiconductor substrate, to selectively etch the above-mentioned silicon oxide-based insulation membrane. In this operation, first and second steps are carried out in turn. In the above-mentioned first step, an etching treatment is carried out under the condition where deposition property of a polymer layer is weaker than that in the above-mentioned second step. In the subsequently second step, an etching treatment is carried out after changing the condition where deposition property of the polymer layer is stronger than that in the above-mentioned first step. More specifically, this method is characterized by containing the first step in low deposition property and the subsequently second step in lower deposition property than in the first step. In this method, distortion formation of the mask during etching of silicon oxide can not be prevented, thus, distortion of an opening can not be suppressed.

### SUMMARY OF THE INVENTION

An object of the present invention is to provide a method for producing a semiconductor device which is capable of forming a deep hole contact ultra-finely without generating distortion of an opening and Twisting in a contact hole.

Another object of the present invention is to provide a method for producing a semiconductor device which is capable of suppressing lowering in yield occurring in forming a contact hole and producing a semiconductor device with high reliability.

Hereinafter, means for solving the problem will be explained using numbers and marks to be used in “DETAILED DESCRIPTION OF PREFERRED EMBODIMENTS”. These numbers and marks are added with brackets for clarifying correspondent relation between the description in claims and the preferred embodiments for carrying out the invention. These number and marks should not be used for interpretation of the technical scope of the invention described in claims.

For solving the above-mentioned problem, the method for producing a semiconductor device of the present invention has the steps of: (a) forming a contact hole (6) in an upper part of an insulation layer (3) containing silicon oxide by dry etching using a first etching gas which contains Xe gas, and (b) deepening the contact hole (7) in the insulation layer (3) by dry etching using a second etching gas which does not contain Xe gas.

In the present invention, when a deep hole contact is formed in a layer containing silicon oxide, dry etching is carried out in the step (a) using a first etching gas which contains Xe gas. By addition of Xe gas, etching can be performed under the condition where the mask surface is smooth, without generating irregularity on the surface of the mask for formation of a contact hole. By this, distortion of the contact hole opening can be suppressed. Next, in the step (b), a second etching gas which does not contain Xe gas is used. By addition of no Xe gas, bending of a contact hole called Twisting can be avoided even if a deeper contact hole is formed. Thus, by changing the kind of the etching gas between earlier period and later period of etching, it is possible to suppress distortion of an opening and Twisting in a contact hole, and to form a contact hole with high aspect ratio.

In the above-mentioned method for producing a semiconductor device, it is preferable that the first etching gas contains a gas obtained by diluting an etching gas with Xe gas or with a mixed gas of Xe gas and Ar gas.

In the present invention, by use of the gas, etching can be performed under the condition where the mask surface is smooth, without generating irregularity on the surface of the mask for formation of a contact hole.

In the above-mentioned method for producing a semiconductor device, it is preferable that the second etching gas contains a gas obtained by diluting an etching gas with Ar gas.

In the present invention, by use of the gas, bending of a contact hole called Twisting can be avoided even if a deeper contact hole is formed.

In the above-mentioned method for producing a semiconductor device, it is preferable that the etching gas contains a mixed gas of a fluorocarbon gas and O₂ gas.

In the present invention, examples of the fluorocarbon gas includes C₄F₈, C₅F₈ or C₄F₆ each singly, and a mixed gas combining two or more of these gases.

In the above-mentioned method for producing a semiconductor device, it is preferable that the step (a) and the step (b) are carried out in a same dry etching chamber.

In the present invention, prolonging time of the etching process can be suppressed by performing dry etchings in the two steps in the same chamber.

In the above-mentioned method for producing a semiconductor device, it is preferable that the composition of the first etching gas is continuously changed to the composition of the second etching gas between the step (a) and the step (b).

In the present invention, transition between the etching steps can smoothly be carried out by continuously performing the change of the gas composition between the two steps.

According to the present invention, a deep hole contact can be formed ultra-finely without generating distortion of an opening and Twisting in a contact hole. Thus, it becomes possible to suppress lowering in yield occurring in forming a contact hole and to produce a semiconductor device with high reliability.

### BRIEF DESCRIPTION OF THE DRAWINGS

FIG. 1 is a cross-sectional view of a semiconductor device having contact holes with high aspect ratio which were formed by a conventional technology.

FIG. 2 is a cross-sectional view of a semiconductor device having contact holes with high aspect ratio which were formed by another conventional technology.

FIG. 3 is a cross-sectional view showing a semiconductor device in one step in an embodiment of the method for producing a semiconductor device of the present invention.

FIG. 4 is a cross-sectional view showing a semiconductor device in one step in an embodiment of the method for producing a semiconductor device of the present invention.

FIG. 5 is a cross-sectional view showing a semiconductor device in one step in an embodiment of the method for producing a semiconductor device of the present invention.

FIG. 6 is a cross-sectional view showing a semiconductor device in one step in an embodiment of the method for producing a semiconductor device of the present invention.

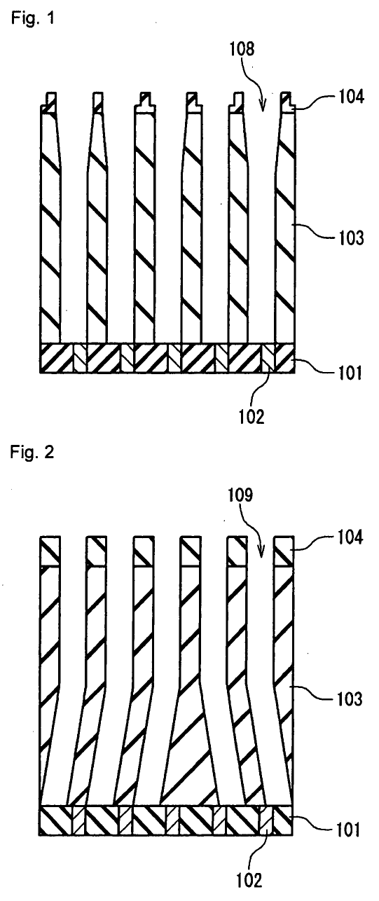

### DETAILED DESCRIPTION OF PREFERRED EMBODIMENTS

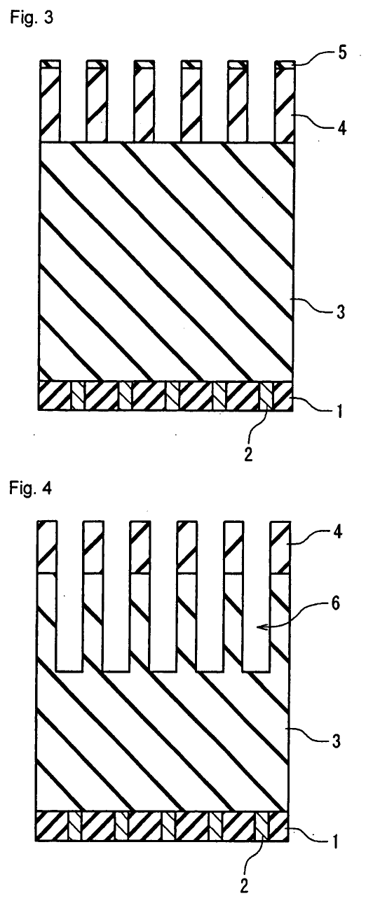

Hereinafter, embodiments of the method for producing a semiconductor device of the present invention will be explained with reference to the accompanying drawings. FIGS. 3 to 6 are cross-sectional views showing a semiconductor device in each step in an embodiment of the method for producing a semiconductor device of the present invention.

The semiconductor device in the process shown in FIG. 3 has an interlayer insulation membrane 1, a contact 2 and an interlayer insulation membrane 3. On the interlayer insulation membrane 3, a mask 4 and an insulation membrane 5 for mask patterning are formed. More specifically, in the method for producing this semiconductor device, FIG. 3 shows the condition after carrying out the steps of forming the interlayer insulation membrane 1, forming the contact 2 in the interlayer insulation membrane 1, forming the interlayer insulation membrane 3, and forming the mask 4 and the insulation membrane 5 for mask patterning in order to form a contact hole in the interlayer insulation membrane 3. These steps can be carried out by conventionally known methods.

The contact 2 is buried in the interlayer insulation membrane 1. The contact 2 connects a semiconductor circuit (not shown) on a substrate below the interlayer insulation membrane 1 to a contact (not shown) to be formed in the interlayer insulation membrane 3. The interlayer insulation membrane 3 is provided so as to cover surfaces of the interlayer insulation membrane 1 and the contact 2. The mask 4 and the insulation membrane 5 for mask patterning are provided on the interlayer insulation membrane 3. In the mask 4 and the insulation membrane 5 for mask patterning, a pattern is formed for forming a contact hole (6 and 7: described later) in the interlayer insulation membrane 3. A contact (not shown) to be formed in the contact hole connects the contact 2 to a wiring layer above the interlayer insulation membrane 3.

Typically, the thickness of the interlayer insulation membrane 1 is 700 nm, the diameter of the contact 2 is 100 nm, the thickness of the interlayer insulation membrane 3 is 3 μm, the thickness of the mask 4 is 800 nm, the material of the mask 4 is amorphous carbon, the thickness of the insulation membrane 5 for mask patterning is 80 nm, the material of the insulation membrane 5 for mask patterning is a laminate of silicon oxide and silicon oxynitride, and the diameter of a hole for the contact hole after patterning the mask 4 and the insulation membrane 5 for mask patterning is 150 nm. That is, the diameter of the contact hole (6 and 7) is approximately 150 nm.

Under the condition shown in FIG. 3, a contact (hereinafter, “first contact” (not shown)) for connecting the contact 2 to a wiring layer as an upper layer of the interlayer insulation membrane 3 is necessary. More specifically, the first contact penetrates the interlayer insulation membrane 3. The first contact is required to connect only to the contact 2 directly below according to the shape of the mask 4 and not to connect to another contact 2 (e.g. adjacent contact 2). Additionally, it is required that the first contacts do not come into contact with each other.

On the semiconductor device under the condition shown in FIG. 3, the first dry etching step is carried out. As a dry etching apparatus is used a bi-frequency RIE apparatus which can apply RF electric power to an upper ground electrode and a lower electrode on a semiconductor wafer. Here, C₄F₆, C₄F₈, O₂, Ar and Xe are used as the etching gas. The gas flow rates are, for example, C₄F₆=5 sccm, C₄F₈=20 sccm, O₂=16 sccm, Ar=110 sccm and Xe=110 sccm. Typically, the etching pressure is 30 mTorr, the bi-frequency RF electric powers applied to the lower electrode are respectively 2000 W and 300 W, and the etching time is 2 minutes. After completion of the first dry etching step, the shape of the mask 4 is required to be smooth with no bump. The contact hole 6 formed by the first dry etching step should have the depth which is shallower than the depth in which Twisting is generated. The depth in which Twisting is generated is, for example, 1.4 μm or more. Here, the depth of the contact hole 6 formed by the first dry etching step was about 1.2 μm which is shallower than the depth in which Twisting is generated. FIG. 4 shows the condition of the semiconductor device after the first dry etching step.

In FIG. 4, the contact hole 6 formed by the first dry etching step is formed at a depth of about 1.2 μm from the upper surface of the interlayer insulation membrane 3 which has a thickness of 3 μm. At this depth, Twisting is never generated. Although the insulation membrane 5 for mask patterning is etched by the first dry etching step, no bump is formed on the surface of the mask 4 due to using Xe-containing gas, and thereby etching can be performed under the condition of the smooth surface of the mask 4. Thus, distortion of an opening of the contact hole 6 can be suppressed.

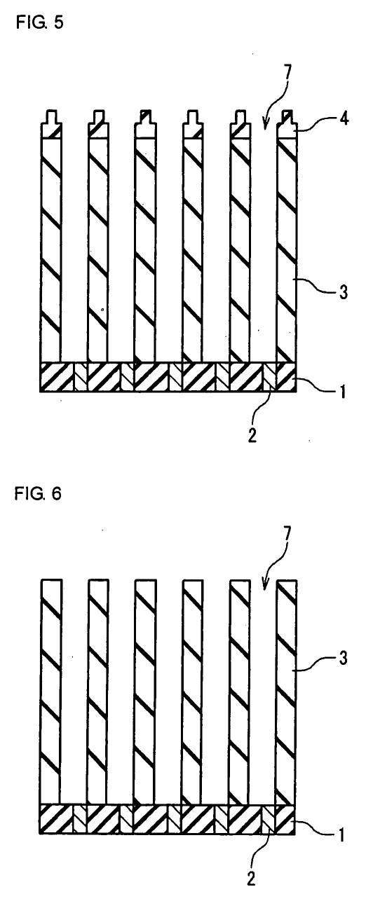

On the semiconductor device under the condition shown in FIG. 4, the second dry etching step is carried out. The second dry etching step is preferably carried out in the same chamber of the same dry etching apparatus. By performing the dry etchings in the same chamber, prolonging time of the etching process can be suppressed. Here, C₄F₆, C₄F₈, O₂ and Ar are used as the etching gas. Xe gas is not used. The gas flow rates are, for example, C₄F₆=10 sccm, C₄F₈=15 sccm, O₂=17 sccm and Ar=160 sccm. Typically, the etching pressure is 30 mTorr, the bi-frequency RF electric powers applied to the lower electrode are respectively 2000 W and 300 W, and the etching time is 4 minutes and 30 seconds. By this, dry etching is further performed in the contact hole 6 to form a contact hole 7 deeper than the contact hole 6. The contact hole 7 penetrates the interlayer insulation membrane 3, reaching the upper surface of the contact 2. FIG. 5 shows this condition.

In FIG. 5, a bump is formed in the mask 4 because only Ar gas is used as the dilution gas. However, in the present invention, the mask 4 can remain surely until completion of the second dry etching step because the time when only Ar gas is used as the dilution gas (the time for second dry etching step) is shorter than that in a conventional case. Therefore, even if a bump is formed on the mask 4, excessive widening of the opening of the contact hole 7 can be prevented. Further, generation of Twisting can be prevented, irrespective of larger depth of the contact hole 7, because only Ar gas is used as the dilution gas. Here, it is preferable that the first dry etching step and the second dry etching step are carried out continuously and irrelevant other steps are not inserted between these steps. By this, the above-mentioned effect can be obtained more surely and the shape of the contact hole can be made smooth.

In the semiconductor device under the condition shown in FIG. 5, the mask 4 removed. FIG. 6 shows this condition. Under the condition shown in FIG. 6, a first contact (not shown) is formed in the contact hole 7 by a conventionally known method.

By such a process, a deep hole contact having ultra fine diameter can be formed in the interlayer insulation membrane 3 in a process for producing a semiconductor device, even under the condition of mutually extremely adjacent closely-spaced arrangement. That is, deformation of the mask 4 such as formation of bump can be prevented in the first etching step, and Twisting can be suppressed in the second etching step. By this, it becomes possible to suppress mutual short circuit between the first contacts (mutual contact of contact holes 7) and to attain secure contact of the first contact formed in the contact hole 7 with the contact 2.

Here, the ultra fine diameter is about 200 nm or less. The deep hole is a hole having a depth of about 2 μm or more. The mutually extremely adjacent closely-spaced condition is a case of mutual adjacency with a distance of about diameter (about 200 nm or less). When the contact under such condition is formed, the present invention can particularly achieve the effect.

The fluorocarbon gas to be used in the first and second dry etching steps may be not only the above-mentioned embodiment, but also C₄F₈, C₅F₈ and C₄F₆ each singly, and a mixed gas combining two or more of these gases. Further, it is also possible to use another fluorocarbon gas.

Xe gas to be used in the first dry etching step may also be a mixed gas of Xe gas and Ar gas. By this, the cost can be reduced. Further, a gas obtained by mixing the above-mentioned gases further with an inert gas against this dry etching may be used.

Still further, when the etching gas is changed from C₄F₆, C₄F₈, O₂, Ar and Xe to C₄F₆, C₄F₈, O₂ and Ar between the first and second dry etching steps, it may be carried out as follows. That is, the composition of the etching gas may be continuously changed during the changing period by changing the flow rate of each gas continuously. By continuously performing the change of the gas composition between two steps, transition between the etching steps can smoothly be carried out.

Even if only Ar gas or only Xe gas is used in the above-mentioned dry etching steps and only the change of their gas flow rates is performed, it is impossible to realize both of suppression of the abnormal deformation of the opening and suppression of Twisting. In the present invention, the first etching step using Xe-containing gas which can suppress deformation of the mask 4 and the second etching step which can suppress Twisting are performed continuously. Thus, it becomes possible to suppress abnormal deformation of the opening of the contact hole 7 and mutual contact of the first contacts due to the deformation, and to attain secure contact of the first contact with the contact 2.

What is claimed is:

1. A method for producing a semiconductor device, comprising the steps of:
(a) forming a contact hole in an upper part of an insulation layer comprising silicon oxide by dry etching using a first etching gas which comprises Xe gas, and
(b) deepening the contact hole in the insulation layer by dry etching using a second etching gas which does not comprise Xe gas.

2. The method for producing a semiconductor device according to claim 1, wherein the first etching gas comprises a gas obtained by diluting an etching gas with Xe gas or with a mixed gas of Xe gas and Ar gas.

3. The method for producing a semiconductor device according to claim 1, wherein the second etching gas comprises a gas obtained by diluting an etching gas with Ar gas.

4. The method for producing a semiconductor device according to claim 2, wherein the second etching gas comprises a gas obtained by diluting an etching gas with Ar gas.

5. The method for producing a semiconductor device according to claim 2, wherein the etching gas comprises a mixed gas of a fluorocarbon gas and O₂ gas.

6. The method for producing a semiconductor device according to claim 3, wherein the etching gas comprises a mixed gas of a fluorocarbon gas and O₂ gas.

7. The method for producing a semiconductor device according to claim 4, wherein the etching gas comprises a mixed gas of a fluorocarbon gas and O₂ gas.

8. The method for producing a semiconductor device according to claim 1, wherein the step (a) and the step (b) are carried out in a same dry etching chamber.

9. The method for producing a semiconductor device according to claim 2, wherein the step (a) and the step (b) are carried out in a same dry etching chamber.

10. The method for producing a semiconductor device according to claim 3, wherein the step (a) and the step (b) are carried out in a same dry etching chamber.

11. The method for producing a semiconductor device according to claim 4, wherein the step (a) and the step (b) are carried out in a same dry etching chamber.

12. The method for producing a semiconductor device according to claim 5, wherein the step (a) and the step (b) are carried out in a same dry etching chamber.

13. The method for producing a semiconductor device according to claim 6, wherein the step (a) and the step (b) are carried out in a same dry etching chamber.

14. The method for producing a semiconductor device according to claim 7, wherein the step (a) and the step (b) are carried out in a same dry etching chamber.

15. The method for producing a semiconductor device according to claim 8, wherein the composition of the first etching gas is continuously changed to the composition of the second etching gas between the step (a) and the step (b).

16. The method for producing a semiconductor device according to claim 9, wherein the composition of the first etching gas is continuously changed to the composition of the second etching gas between the step (a) and the step (b).

17. The method for producing a semiconductor device according to claim 10, wherein the composition of the first etching gas is continuously changed to the composition of the second etching gas between the step (a) and the step (b).

18. The method for producing a semiconductor device according to claim 11, wherein the composition of the first etching gas is continuously changed to the composition of the second etching gas between the step (a) and the step (b).

19. The method for producing a semiconductor device according to claim 12, wherein the composition of the first etching gas is continuously changed to the composition of the second etching gas between the step (a) and the step (b).

20. The method for producing a semiconductor device according to claim 13, wherein the composition of the first etching gas is continuously changed to the composition of the second etching gas between the step (a) and the step (b).

21. The method for producing a semiconductor device according to claim 14, wherein the composition of the first etching gas is continuously changed to the composition of the second etching gas between the step (a) and the step (b).
